(19) United States
(12) Patent Application Publication
(10) Pub. No.: US 2007/0145894 A1
(43) Pub. Date: Jun. 28, 2007

(54) Organic electroluminescence device and producing method thereof

(75) Inventors: Tasuka Satou, Kanagawa (JP); Watanu Sotoyama, Kanagawa (JP)

Correspondence Address: BIRCH STEWART KOLASCH & BIRCH, PO BOX 747, FALLS CHURCH, VA, 22040-0747, US

(73) Assignee: FUJIFILM Corporation

(21) Appl. No.: 11/643,670

(22) Filed: Dec. 22, 2006

(30) Foreign Application Priority Data
Dec. 27, 2005 (JP) 2005-375883

(51) Int. Cl. H01L 51/52; H01L 51/56

(52) U.S. Cl. 313/506; 428/690; 428/917; 313/512; 313/113; 427/66; 257/98; 257/99; 257/100; 257/E51.02; 257/E51.021

(57) ABSTRACT

An organic electroluminescence device including on a substrate, in the following order, a first electrode, at least an organic compound layer including a light-emitting layer, a second electrode, and a protective layer, wherein the protective layer includes two or more layers, a first protective layer closer to the second electrode is an electrically insulating layer containing an organic compound, and a second protective layer farther from the second electrode is a layer containing a metal halide. An organic electroluminescence device improved in storage stability and, in particular, strong in durability with respect to moisture and oxygen, and a producing method thereof is provided.

### CROSS-REFERENCE TO RELATED APPLICATION

This application claims priority under 35 USC 119 from Japanese Patent Application No. 2005-375883, the disclosure of which is incorporated by reference herein.

### BACKGROUND OF THE INVENTION

1. Field of the Invention

The present invention relates to an organic electroluminescence device and a producing method thereof. In particular, the present invention relates to an organic electroluminescence device having improved storage stability and a producing method thereof.

2. Description of the Related Art

An organic electroluminescence device that uses a thin film material that is excited to emit light upon applying a current is known. The organic electroluminescence device can obtain bright emission at low voltages. Accordingly, in broad fields including portable telephone displays, personal digital assistants (PDA), computer displays, automobile information displays, TV monitors and general illumination, the organic electroluminescence devices have broad latent applications. In those fields, the organic electroluminescence devices are advantageous with respect to thinning, weight reduction, miniaturization and power saving. Accordingly, the organic electroluminescence device is greatly expected to be a major player in the future electronic display market. However, in order to be used in these fields in place of existing displays, technical improvements with respect to many points such as emission brightness and color tone, durability under broad environmental usage conditions and mass productivity at low costs have to be achieved.

One important problem of the organic electroluminescence device is that it is very weak with respect to moisture and oxygen. Specifically, various phenomena such as an interface between a metal electrode and an organic layer being denatured under the influence of moisture, an electrode being peeled off, a metal electrode being oxidized and becoming highly resistive, and an organic material itself being denatured due to moisture are caused.

As a result, there is a problem in that a increase in driving voltage, generation and growth of dark spots (non-emitting defects), a decrease in emission brightness or the like occurs, and sufficient reliability cannot be maintained.

In Japanese Patent No. 3170542, an attempt is proposed wherein an organic electroluminescence device is disposed on a substrate, and on the surface thereof an inorganic material layer is further deposited as a protective layer to form a sealing layer to moisture. As the inorganic material, silicon nitride, silicon oxynitride, silicon carbide and amorphous silicon are disclosed. However, a film deposited on an organic compound layer has a problem in that defects such as pinholes and cracks often occur. In order to eliminate these defects, a deposition thickness of the inorganic material may be considerably thickened or the deposition may be repeated a plurality of times to form a multi-layered film. However, these means are not preferred from the viewpoints of cost and productivity.

Furthermore, Japanese Patent Application Laid-Open (JP-A) No. 6-96858 discloses disposing, as a protective layer for inhibiting moisture penetration, a metal halide layer by means of an ion plating method, and JP-A No. 2000-338755 discloses coating an epoxy resin containing a metal halide using an organic solvent. As the metal halide, lithium fluoride is disclosed. The metal halide, being hygroscopic, adsorbs moisture to prevent intrusion of moisture from outside. However, on the other hand, there is a problem in that, since the moisture is gradually effused so as to diffuse to a light-emitting layer when the adsorbed moisture approaches a saturation amount, the light-emitting layer is damaged by the moisture. Thus, the metal halide layer as a protective layer was not a sufficient solution to the problem. Furthermore, in the ion plating process, since an element is exposed to a high temperature, the light-emitting layer is damaged, and when an organic solvent is used to coat, the organic solvent remains in the element. In each of these cases, there is a problem in that emission performance of the organic electroluminescence device is adversely affected.

JP-A No. 7-169567 discloses a means wherein a moisture absorbent is added to a protective layer to inhibit moisture intrusion. However, similarly to the case where the metal halide layer is disposed as a protective layer, there is a problem in that the moisture absorbent gradually effuses adsorbed or absorbed moisture to damage the light-emitting layer.

Thus, a sealing method that is excellent in the protection with respect to moisture and has sufficient productivity as a producing method is desired.

### SUMMARY OF THE INVENTION

The present invention has been made in view of the above circumstances and provides an organic electroluminescence device comprising on a substrate, in the following order, a first electrode, at least an organic compound layer including a light-emitting layer, a second electrode, and a protective layer, wherein the protective layer includes two or more layers, a first protective layer closer to the second electrode is an electric insulating layer containing an organic compound, and a second protective layer farther from the second electrode is a layer containing a metal halide.

Furthermore, the present invention provides a producing method of an organic electroluminescence device that includes, on a substrate, in the following order, a first electrode, at least an organic compound layer including a light-emitting layer, a second electrode and a protective layer, wherein the protective layer includes two or more layers, a first protective layer closer to the second electrode being an electric insulating layer containing an organic compound, and a second protective layer farther from the second electrode being a metal halide layer, wherein the producing method comprises a process of sequentially forming the electrodes and the respective layers by means of a resistance heating vacuum deposition method.

### DETAILED DESCRIPTION OF THE INVENTION

The present invention provides an organic electroluminescence device having improved storage stability and driving stability and a producing method thereof, and in particular, provides an organic electroluminescence device having strong durability with respect to moisture and oxygen and a producing method thereof.

1. Organic Electroluminescence Device

An organic electroluminescence device in the present invention may have, in addition to the light-emitting layer, conventionally known organic compound layers such as a positive hole-transport layer, an electron-transport layer, a blocking layer, an electron-injection layer and a positive hole-injection layer.

In the following, the organic electroluminescence device of the present invention will be described in detail.

1) Layer Configuration

<Electrode>

At least one of a pair of electrodes of the organic electroluminescence device of the present invention is a transparent electrode, and the other one is a rear surface electrode. The rear surface electrode may be transparent or non-transparent.

<Configuration of Organic Compound Layer>

A layer configuration of the at least one organic compound layer can be appropriately selected, without particular restriction, depending on an application of the organic electroluminescence device and an object thereof. However, the organic compound layers are preferably formed on the transparent electrode or the rear surface electrode. In these cases, the organic compound layers are formed on front surfaces or one surface on the transparent electrode or the rear surface electrode.

A shape, magnitude and thickness of the organic compound layers can be appropriately selected, without particular restriction, depending on applications thereof.

Examples of specific layer configurations include those cited below, but the present invention is not restricted to those configurations.

Anode/positive hole-transport layer/light-emitting layer/electron-transport layer/cathode,

Anode/positive hole-transport layer/light-emitting layer/blocking layer/electron-transport layer/cathode,

Anode/positive hole-transport layer/light-emitting layer/blocking layer/electron-transport layer/electron-injection layer/cathode,

Anode/positive hole-injection layer/positive hole-transport layer/light-emitting layer/blocking layer/electron-transport layer/cathode, and

Anode/positive hole-injection layer/positive hole-transport layer/light-emitting layer/blocking layer/electron-transport layer/electron-injection layer/cathode.

In the following, the respective layers will be described in detail.

2) Positive Hole-Transport Layer

The positive hole-transport layer that is used in the present invention includes a positive hole transporting material. For the positive hole transporting material, any material can be used without particular restriction as far as it has either one of a function of transporting holes or a function of blocking to electrons injected from the cathode. As the positive hole transporting material that can be used in the present invention, either one of a low molecular weight hole transporting material and a polymer hole transporting material can be used.

Specific examples of the positive hole transporting material that can be used in the present invention include a carbazole derivative, a triazole derivative, an oxazole derivative, an oxadiazole derivative, an imidazole derivative, a polyarylalkane derivative, a pyrazoline derivative, a pyrazolone derivative, a phenylenediamine derivative, an arylamine derivative, an amino-substituted chalcone derivative, a styrylanthracene derivative, a fluorenone derivative, a hydrazone derivative, a stilbene derivative, a silazane derivative, an aromatic tertiary amine compound, a styrylamine compound, an aromatic dimethylidene-based compound, a porphyrin-based compound, a polysilane-based compound, a poly(N-vinylcarbazole) derivative, an aniline-based copolymer, electric conductive polymers or oligomers such as a thiophene oligomer and polythiophene, and polymer compounds such as a polythiophene derivative, a polyphenylene derivative, a polyphenylenevinylene derivative and a polyfluorene derivative.

These compounds may be used singularly or in a combination of two or more.

A thickness of the positive hole-transport layer is preferably 10 nm to 400 nm and more preferably 50 nm to 200 nm.

3) Hole-Injection Layer

In the present invention, a positive hole-injection layer may be disposed between the positive hole-transport layer and the anode.

The positive hole-injection layer is a layer that makes it easy for holes to be injected easily from the anode to the positive hole-transport layer, and specifically, a material having a small ionization potential among the positive hole transporting materials cited above is preferably used. For instance, a phthalocyanine compound, a porphyrin compound and a star-burst type triarylamine compound can be preferably used.

A film thickness of the positive hole-injection layer is preferably 1 nm to 300 nm.

4) Light-Emitting Layer

A light-emitting layer in the present invention comprises at least one light emitting material, and may comprise as necessary other compounds such as a positive hole transporting material, an electron transporting material, and a host material.

Any of light emitting materials can be used without particular restriction. Either of fluorescent emission materials or phosphorescent emission materials can be used, but the phosphorescent emission materials are preferred in view of the luminescent efficiency.

Examples of the above-described fluorescent emission materials include, for example, a benzoxazole derivative, a benzimidazole derivative, a benzothiazole derivative, a styrylbenzene derivative, a polyphenyl derivative, a diphenylbutadiene derivative, a tetraphenylbutadiene derivative, a naphthalimide derivative, a coumarin derivative, a perylene derivative, a perinone derivative, an oxadiazole derivative, an aldazine derivative, a pyralidine derivative, a cyclopentadiene derivative, a bis-styrylanthracene derivative, a quinacridone derivative, a pyrrolopyridine derivative, a thiadiazolopyridine derivative, a styrylamine derivative, aromatic dimethylidene compounds, a variety of metal complexes represented by metal complexes or rare-earth complexes of 8-quinolynol, polymer compounds such as polythiophene, polyphenylene and polyphenylenevinylene, organic silanes, and the like. These compounds may be used singularly or in a combination of two or more.

The phosphorescent emission material is not particularly limited, but an ortho-metal complex or a porphyrin metal complex is preferred.

The ortho-metal complex referred to herein is a generic designation of a group of compounds described in, for instance, Akio Yamamoto, Yuki Kinzoku Kagaku, Kiso to Oyo (“Organic Metal Chemistry, Fundamentals and Applications”)(Shokabo, 1982), pp. 150 and 232, and H. Yersin, Photochemistry and Photophysics of Coordination Compounds (New York: Springer-Verlag, 1987), pp. 71-77 and pp. 135-146. The ortho-metal complex can be advantageously used as a light emitting material because high brightness and excellent emitting efficiency can be obtained.

As a ligand that forms the ortho-metal complex, various kinds can be cited and are described in the above-mentioned literature as well. Examples of preferable ligands include a 2-phenylpyridine derivative, a 7,8-benzoquinoline derivative, a 2-(2-thienyl)pyridine derivative, a 2-(1 -naphtyl)pyridine derivative and a 2-phenylquinoline derivative. The derivatives may be substituted by a substituent as needs arise. Furthermore, the ortho-metal complex may have other ligands than the ligands mentioned above.

An ortho-metal complex used in the present invention can be synthesized according to various kinds of known processes such as those described in Inorg. Chem., 1991, Vol. 30, pp. 1685; Inorg. Chem., 1988, Vol. 27, pp. 3464; Inorg. Chem., 1994, Vol. 33, pp. 545; Inorg. Chim. Acta, 1991, Vol. 181, pp. 245; J. Organomet. Chem., 1987, Vol. 335, pp. 293 and J. Am. Chem. Soc., 1985, Vol. 107, pp. 1431.

Among the ortho-metal complexes, compounds emitting from a triplet exciton can be preferably employed in the present invention from the viewpoint of improving emission efficiency.

Furthermore, among the porphyrin metal complexes, a porphyrin platinum complex is preferable.

The phosphorescent light emitting materials may be used singularly or in a combination of two or more. Furthermore, a fluorescent emission material and a phosphorescent emission material may be simultaneously used.

A host material is a material that has a function of causing an energy transfer from an excited state thereof to the fluorescent emission material or the phosphorescent emission material to cause light emission from the fluorescent emission material or the phosphorescent emission material.

As the host material, as long as a compound can transfer exciton energy to a light emitting material, any compound can be appropriately selected and used depending on an application without particular restriction. Specific examples thereof include: a carbazole derivative; a triazole derivative; an oxazole derivative; an oxadiazole derivative; an imidazole derivative; a polyarylalkane derivative; a pyrazoline derivative; a pyrazolone derivative; a phenylenediamine derivative; an arylamine derivative; an amino-substituted chalcone derivative; a styrylanthracene derivative; a fluorenone derivative; a hydrazone derivative; a stilbene derivative; a silazane derivative; an aromatic tertiary amine compound; a styrylamine compound; an aromatic dimethylidene-based compound; a porphyrin-based compound; an anthraquinonedimethane derivative; an anthrone derivative; a diphenylquinone derivative; a thiopyran dioxide derivative; a carbodiimide derivative; a fluorenylidenemethane derivative; a distyrylpyrazine derivative; heterocyclic tetracarboxylic anhydrides such as naphthalene perylene; a phthalocyanine derivative; various kinds of metal complexes typified by metal complexes of a 8-quinolinol derivative, metal phthalocyanine, and metal complexes with benzoxazole or benzothiazole as a ligand; polysilane compounds; a poly(N-vinylcarbazole) derivative; an aniline-based copolymer; electric conductive polymers or oligomers such as a thiophene oligomer and polythiophene; polymer compounds such as a polythiophene derivative, a polyphenylene derivative, a polyphenylenevinylene derivative and a polyfluorene derivative; and like. These compounds can be used singularly or in a combination of two or more.

A content of the host material in the light-emitting layer is preferably in the range of 0 to 99.9 mass percent and more preferably in the range of 0 to 99.0 mass percent.

5) Blocking Layer

In the present invention, a blocking layer may be disposed between the light-emitting layer and the electron-transport layer. The blocking layer is a layer that inhibits excitons generated in the light-emitting layer from diffusing and holes from penetrating to a cathode side.

A material that is used in the blocking layer may be a general electron transporting material, as long as it can receive electrons from the electron-transport layer and deliver them to the light-emitting layer, without being particularly restricted. Examples thereof include a triazole derivative; an oxazole derivative; an oxadiazole derivative; a fluorenone derivative; an anthraquinodimethane derivative; an anthrone derivative; a diphenylquinone derivative; a thiopyran dioxide derivative; a carbodiimide derivative; a fluorenylidenemethane derivative; a distyrylpyrazine derivative; heterocyclic tetracarboxylic anhydrides such as naphthalene perylene; a phthalocyanine derivative; various kinds of metal complexes typical in metal complexes of a 8-quinolinol derivative, metal phthalocyanine, and metal complexes with benzoxazole or benzothiazole as a ligand; electric conductive polymer oligomers such as an aniline-based copolymer, a thiophene oligomer and polythiophene; and polymer compounds such as a polythiophene derivative, a polyphenylene derivative, a polyphenylenevinylene derivative and a polyfluorene derivative. These can be used singularly or in a combination of two or more.

6) Electron-Transport Layer

In the present invention, an electron-transport layer including an electron transporting material can be disposed.

The electron transporting material can be used without particular restriction, as long as it has either one of a function of transporting electrons or a function of blocking holes injected from the an anode. The electron transporting materials that were cited in the explanation of the blocking layer can be preferably used.

A thickness of the electron-transport layer is preferably 10 nm to 200 nm and more preferably 20 nm to 80 nm.

When the thickness exceeds 1000 nm, the driving voltage increases in some cases. When it is less than 10 nm, the light-emitting efficiency of the light-emitting element may be greatly deteriorated, which is not preferable.

7) Electron-Injection Layer

In the present invention, an electron-injection layer can be disposed between the electron-transport layer and the cathode.

The electron-injection layer is a layer by which electrons can be readily injected from the cathode to the electron-transport layer. Specifically, lithium salts such as lithium fluoride, lithium chloride and lithium bromide; alkali metal salts such as sodium fluoride, sodium chloride and cesium fluoride; and electric insulating metal oxides such as lithium oxide, aluminum oxide, indium oxide and magnesium oxide can be preferably used.

A film thickness of the electron-injection layer is preferably 0.1 nm to 5 nm.

8) Substrate

The substrate to be applied in the present invention is preferably impermeable to moisture or very slightly permeable to moisture. Furthermore, the substrate preferably does not scatter or attenuate light emitted from the organic compound layer. Specific examples of materials for the substrate include YSZ ( zirconia-stabilized yttrium); inorganic materials such as glass; polyesters such as polyethylene terephthalate, polybutylene phthalate and polyethylene naphthalate; and organic materials such as polystyrene, polycarbonate, polyethersulfon, polyarylate, aryldiglycolcarbonate, polyimide, polycycloolefin, norbornene resin, poly(chlorotrifluoroethylene), and the like.

In case of employing an organic material, it is preferred to use a material excellent in heat resistance, dimensional stability, solvent-resistance, electrical insulation, workability, low air-permeability, and low moisture-absorption. These can be used singularly or in a combination of two or more.

There is no particular limitation as to the shape, the structure, the size and the like of the substrate, but it may be suitably selected according to the application, the purposes and the like of the luminescent device. In general, a plate-like substrate is preferred as the shape of the substrate. The structure of the substrate may be a monolayer structure or a laminated structure. Furthermore, the substrate may be formed from a single member or from two or more members.

Although the substrate may be in a transparent and colorless, or a transparent and colored condition, it is preferred that the substrate is transparent and colorless from the viewpoint that the substrate does not scatter or attenuate light emitted from the organic emissive layer.

A moisture permeation preventive layer (gas barrier layer) may be provided on the front surface or the back surface of the substrate.

For a material of the moisture permeation preventive layer (gas barrier layer), inorganic substances such as silicon nitride and silicon oxide may be preferably applied. The moisture permeation preventive layer (gas barrier layer) may be formed in accordance with, for example, a high-frequency sputtering method or the like.

In case of applying a thermoplastic substrate, a hard-coat layer or an under-coat layer may be further provided as necessary.

9) Electrodes

Either one of the first electrode and the second electrode in the present invention can be an anode or a cathode. It is preferable that the first electrode is the anode and the second electrode is the cathode.

<Anode>

An anode in the present invention may generally have a function as an electrode for supplying positive holes to the organic compound layer, and while there is no particular limitation as to the shape, the structure, the size and the like, it may be suitably selected from among well-known electrode materials according to the application and the purpose thereof.

As materials for the anode, for example, metals, alloys, metal oxides, electric conductive compounds, and mixtures thereof are preferably used, wherein those having a work function of 4.0 eV or more are preferred. Specific examples of the anode materials include electric conductive metal oxides such as tin oxides doped with antimony, fluorine or the like (ATO, and FTO), tin oxide, zinc oxide, indium oxide, indium tin oxide (ITO), and indium zinc oxide (IZO); metals such as gold, silver, chromium, and nickel; mixtures or laminates of these metals and the electric conductive metal oxides; inorganic electric conductive materials such as copper iodide, and copper sulfide; organic electric conductive materials such as polyaniline, polythiophene, and polypyrrole; and laminates of these inorganic or organic electron-conductive materials with ITO.

The anode may be formed on the substrate, for example, in accordance with a method which is appropriately selected from among wet methods such as a printing method, and a coating method and the like; physical methods such as a vacuum deposition method, a sputtering method, and an ion plating method and the like; and chemical methods such as CVD and plasma CVD methods and the like with consideration of the suitability with a material constituting the anode. For instance, when ITO is selected as a material for the anode, the anode may be formed in accordance with a DC or high-frequency sputtering method, a vacuum deposition method, an ion plating method or the like.

In the organic electroluminescence device of the present invention, a position at which the anode is to be formed is not particularly restricted, but it may be suitably selected according to the application and the purpose of the luminescent device. The anode may be formed on either the whole surface or a part of the surface on either side of the substrate.

For patterning to form the anode, a chemical etching method such as photolithography, a physical etching method such as etching by laser, a method of vacuum deposition or sputtering through superposing masks, and a lift-off method or a printing method may be applied.

A thickness of the anode may be suitably selected dependent on the material constituting the anode, and is not definitely decided, but it is usually in the range of around 10 nm to 50 μm, and 50 nm to 20 μm is preferred.

A value of electric resistance of the anode is preferably 10³ Ω/□ or less, and 10² Ω/□ or less is more preferable.

The anode in the present invention can be colorless and transparent or colored and transparent. For extracting luminescence from the transparent anode side, it is preferred that a light transmittance of the anode is 60% or higher, and more preferably 70% or higher. The light transmittance in the present invention can be measured by means well known in the art using a spectrophotometer.

Concerning the transparent anode, there is a detailed description in “TOUMEI DENNKYOKU-MAKU NO SHINTENKAI (Novel Developments in Transparent Electrode Films)” edited by Yutaka Sawada and published by C.M.C. in 1999, the contents of which are incorporated by reference herein. In the case where a plastic substrate of a low heat resistance is applied, it is preferred that ITO or IZO is used to obtain a transparent anode prepared by forming the film at a low temperature of 150° C. or lower.

<Cathode>

The cathode in the present invention may generally have a function as an electrode for injecting electrons to the organic compound layer, and there is no particular restriction as to the shape, the structure, the size and the like. Accordingly, the cathode may be suitably selected from among well-known electrode materials.

As the materials constituting the cathode, for example, metals, alloys, metal oxides, electric conductive compounds, and mixtures thereof may be used, wherein materials having a work function of 4.5 eV or less are preferred. Specific examples thoseof include alkali metals (e.g., Li, Na, K, Cs or the like); alkaline earth metals (e.g., Mg, Ca or the like); gold; silver; lead; aluminum; sodium-potassium alloys; lithium-aluminum alloys; magnesium-silver alloys; rare earth metals such as indium and ytterbium; and the like. They may be used alone, but it is preferred that two or more of them are used in combination from the viewpoint of satisfying both of stability and electron injectability.

Among these, as the materials for constituting the cathode, alkaline metals or alkaline earth metals are preferred in view of electron injectability, and materials containing aluminum as the major component are preferred in view of excellent preservation stability.

The term “material containing aluminum as the major component” refers to a material that material exists in the form of aluminum alone; alloys comprising aluminum and 0.01% by mass to 10% by mass of an alkaline metal or an alkaline earth metal; or mixtures thereof (e.g., lithium-aluminum alloys, magnesium-aluminum alloys and the like).

As for materials for the cathode, they are described in detail in JP-A Nos. 2-15595 and 5-121172, the contents of which are incorporated by reference herein.

A method for forming the cathode is not particularly limited, but it may be formed in accordance with a well-known method. For instance, the cathode may be formed in accordance with a method which is appropriately selected from among wet methods such as a printing method, and a coating method and the like; physical methods such as a vacuum deposition method, a sputtering method, and an ion plating method and the like; and chemical methods such as CVD and plasma CVD methods and the like, while taking the suitability to a material constituting the cathode into consideration. For example, when a metal (or metals) is (are) selected as a material (or materials) for the cathode, one or two or more of them may be applied at the same time or sequentially in accordance with a sputtering method or the like.

For patterning to form the cathode, a chemical etching method such as photolithography, a physical etching method such as etching by laser, a method of vacuum deposition or sputtering through superposing masks, and a lift-off method or a printing method may be applied.

In the present invention, a position at which the cathode is to be formed is not particularly restricted, but it may be formed on either the whole or a part of the organic compound layer.

Furthermore, a dielectric material layer made of a fluoride, an oxide or the like of an alkaline metal or an alkaline earth metal may be inserted in between the cathode and the organic compound layer with a thickness of 0.1 nm to 5 nm, wherein the dielectric layer may serve as one kind of electron injection layer. The dielectric material layer may be formed in accordance with, for example, a vacuum deposition method, a sputtering method, an on-plating method or the like.

A thickness of the cathode may be suitably selected dependent on materials for constituting the cathode and is not definitely decided, but it is usually in the range of around 10 nm to 5 μm, and 50 nm to 1 μm is preferred.

Moreover, the cathode may be transparent or opaque. The transparent cathode may be formed by preparing a material for the cathode with a small thickness of 1 mn to 10 nm, and further laminating a transparent electric conductive material such as ITO or IZO thereon.

10) Protective Layer

A protective layer in the present invention has two or more layers, a first protective layer closer to a second electrode being an electric insulating layer, and a second layer farther from the second electrode being a metal halide layer.

The second protective layer in the present invention inhibits intrusion of moisture from outside. The first protective layer is a diffusion-inhibiting layer. Even when moisture adsorbed by the second protective layer is effused again, the first protective layer inhibits the moisture from diffusing into the light-emitting layer, whreby the moisture is transpired outside of the element. Owing to the synergy effect of these two layers, deterioration of the light-emitting element due to intrusion of moisture or gases such as oxygen can be effectively inhibited.

<First Protective Layer (Electric Insulating Layer)>

In the present invention, an organic layer formed between the organic EL device portion and the metal halide layer is formed to inhibit moisture adsorbed by the metal halide layer having hygroscopicity from damaging the organic EL device thereafter. The organic layer may be a mixture layer made of a plurality of organic compounds, and it is preferable that the organic layer does not crystallize when moisture adsorbed by the metal halide layer or moisture slightly permeated from the air intrudes. That is because the organic layer may adversely affect on the organic EL device in the lower layer upon crystallizing. An organic compound that is used in the organic layer is not particularly restricted, as long as a layer can be formed by means of a resistance-heating vacuum deposition method and does not tend to crystallize. However, in a top emission mode organic EL device, the higher the light transmittance is, the more preferable it is, and the light transmittance in a desired wavelength region is preferably 60% or more.

The organic layer is formed of an electric insulating material that exibits, in a thin film state, electric conductivity lower than that of an upper electrode in contact with the organic EL device by three-digits or more. When the organic layer is electric conductive, a short-circuit is generated between upper electrodes of the organic EL device, to cause cross-talk in a display application, and accordingly, a material having an electric resistance larger than that of the upper electrode has to be used. A thickness of the organic layer is not particularly restricted, as long as it can sufficiently exhibit protective effect. However, it is preferably 10 nm to 1000 nm. In an organic EL device of the top emission mode, the thickness is preferably selected so that the light transmittance in a desired wavelength is 60% or more.

Furthermore, in order to form the layer by means of the resistance-heating vacuum deposition method, an average molecular weight of an organic material that forms the organic layer is preferably 1500 or less, and more preferably 300 to 800. As such organic materials, arylamine-based compounds and condensed cyclic compounds having a bulky substituent which are widely used in organic EL devices can be preferably used, because these are excellent in amorphous stability. For instance, mCP and 2-TNATA are preferable.

The electric insulating organic layer, may contain an additive other than the organic material, as necessory.

As a substance that is contained as an additive in the electric insulating organic layer, any material may be applied as long as it is a material that neither imparts electric conductivity to the layer, nor deteriorates the light transmittance to 60% or less or deteriorates the amorphousness. In particular, since in many cases a mixed layer of organic materials increases the amorphousness, a plurality of organic materials can be preferably mixed.

A thickness of the first protective layer in the present invention is preferably 10 nm to 1000 nm. More preferably, it is 20 nm to 100 nm.

When the thickness is less than 10 nm, the moisture inhibiting property is unfavorably deteriorated. Furthermore, when the thickness is more than 1000 nm, it takes a long time to make the layer, so that it is unfavorable from the viewpoint of process productivity. Moreover, in some cases, the film stress becomes larger, and the film is unfavorably peeled off.

<Second Protective Layer (Metal Halide Layer)>

The metal halide layer in the present invention is disposed to remove moisture that shortens the lifetime of the organic EL device. The layer contains 50% or more of metal halide that has hygroscopicity and is formed by means of a resistance-heating vacuum deposition method. When the metal halide layer is directly brought into contact with the organic EL device, in some cases, absorbed moisture causes dark spots in the organic EL device, and accordingly, an organic layer is disposed between the element and the metal halide layer to inhibit the absorbed moisture from causing adverse effects. A stacked structure of the organic layer/metal halide layer is layered in this order on the organic EL device. The stacked structure may be formed as a repeated structure. For instance, when a two-unit structure of organic layer/metal halide layer/organic layer/metal halide layer is adopted, a material composition may be different between an upper unit and a lower unit. Furthermore, when a stacked structure is arranged in order of organic EL device/organic layer/metal halide layer, a structure having another sealing film or sealing plate thereon is included within the scope of the present invention.

As the material that is used in the metal halide layer, any materials that have hygroscopicity and can form layer by means of the resistance heating vacuum deposition method can be used. For instance, lithium fluoride, calcium fluoride, potassium fluoride, sodium fluoride, magnesium fluoride, sodium chloride, potassium chloride, potassium bromide, lithium chloride, and the like can be preferably used. A film thickness of the metal halide layer may be any thickness as long as it exhibits excellent protective effect. However, it is preferably 10 nm to 1000 nm.

Even when the metal halide layer is used in a top emission mode organic EL device, these metal halides are high in visible light transmittance in a thin film state and can exhibit high protective effect without deteriorating emission of the organic EL device. The film thickness and the material are preferably selected so that the light transmittance is 60% or more at a desired wavelength.

A thickness of the metal halide layer in the present invention is preferably 10 nm to 1000 nm and more preferably 20 nm to 100 nm.

When the thickness is less than 10 nm, the moisture inhibiting function becomes unfavorably insufficient. Furthermore, when it is more than 1000 nm, it takes a long time to make the layer, so that it is unfavorable from the viewpoint of process productivity. Moreover, in some cases, the film stress becomes larger, and the film is unfavorably peeled.

11) Resonance Structure

The organic EL device according to the present invention preferably puts highly bright light by multiply reflecting and resonating at the inside of the element to amplify light having a particular wavelength, generated in the light-emitting layer. A resonator structure that uses a multilayer film mirror and a resonator structure that uses two electrodes that face each other as a mirror can be used as such a resonance structure.

(1) Resonator Structure with Multilayer Film Mirror

An organic electroluminescence device in the present invention that incorporates a resonator structure due to a multilayer film mirror is a micro-optical resonator type organic electroluminescence device. The micro-optical resonator type organic electroluminescence device includes: a multilayer film mirror in which two kinds of layers different in refractive index are alternately stacked; a transparent electric conductive layer as an anode, which is formed on the multilayer film mirror; one or a plurality of organic compound layers formed on the transparent electric conductive layer; and a metal mirror as a cathode, which is formed on the organic compound layer and can reflect light. The multilayer film mirror and the metal mirror constitute a micro-optical resonator of light outputted from the organic compound layer, and an optical length of the micro-optical resonator is set so that light emission from the micro-optical resonator is a single mode in which a low-order mode is not mingled in the spectrum and is light that has strong directionality at the front of the element.

According to the above configuration, owing to the micro-optical resonator constituted from the multilayer film mirror and the metal mirror, light having a particular wavelength among lights outputted from the organic compound layer is resonated and strengthened. Accordingly, light having a desired wavelength can be extracted from lights emitted from the organic compound layer.

Furthermore, according to another embodiment of the invention, in the micro-optical resonator type organic electroluminescence device of the present invention, the optical length L of the micro-optical resonator is expressed by an equation as shown below that takes permeation of light inside of the multilayer film mirror into consideration.
L=(λ/2)(n_{eff}/Δn)+Σnidi cos θ

Herein, n_{eff} expresses an effective refractive index of the multilayer film mirror, Δn expresses the difference between the refractive indices of two layers of the multilayer film mirror, ni and di express the refractive index and a layer thickness of the organic compound layer and the transparent electric conductive layer, respectively, and θ expresses an angle between lights incident on the respective interfaces between the organic compound layers or between the organic compound layer and the transparent electric conductive layer and normal lines to the interfaces, wherein it is characterized that the optical length L thereof is 1.5 times as long as a target emission wavelength.

In the above configuration, a first term of the equation, (λ/2)(n_{eff}/Δn), expresses a depth by which resonated light permeates in the multilayer film mirror. As is obvious from the first term, since n_{eff} and Δn are constants determined by the materials that constitute the multilayer film mirror, provided that a wavelength λ of light is determined, the permeating depth is determined as well. Furthermore, the refractive indices ni of the respective layers in the second term are also determined as well by the materials, and a thickness of each of the layers of the multilayer film mirror is set at λ/4. Accordingly, the optical length L can be controlled by varying the thicknesses di of the transparent electric conductive layer and the organic compound layer.

A wavelength of light that resonates with the micro-optical resonator is determined by the optical length L. That is, light where the optical length L corresponds to an integer multiple of one half of the wavelength thereof can resonate with the micro-optical resonator. Accordingly, when a total thickness of the transparent electric conductive layer and the organic compound layer is made thinner to make the optical length L smaller, a wavelength of light that resonates with the micro-optical resonator and is emitted from the element also varies to a shorter wavelength side. At this time, light where 1.5 times one half the wavelength is equal to the optical length L is the longest wavelength of light that can resonate. Accordingly, light emitted from the element has a wavelength shorter than this. When a wavelength of light emitted from the element becomes shorter, light having high directionality at the front of the element can be obtained. Furthermore, when the optical length L is made smaller, an emission mode of the element can be rendered a single mode.

Furthermore, as still another embodiment, the uppermost layer of the multilayer film mirror can be constituted by a transparent electric conductive layer, and the uppermost layer may serve as both a multilayer film mirror and a transparent electric conductive layer. According to this configuration, since the uppermost layer serves as both the multilayer film mirror and the transparent electric conductive layer, a thickness of the element can serve room by this amount, whereby the transparent electric conductive layer can be made thicker.

Further, according to yet another embodiment, a target emission wavelength is set in a rising-edge portion on a shorter wavelength side of a peak wavelength λm in an emission spectrum of a light emitting material used.

Furthermore, according to another embodiment, the organic compound layer may be formed of any one of a single layer structure made of only a light-emitting layer, a two layer structure made of a positive hole-transport layer and a light-emitting layer or a light-emitting layer and an electron-transport layer, or a three layer structure of a positive hole-transport layer, a light-emitting layer and an electron-transport layer.

Further, according to still another embodiment, the optical length of each of the respective layers of the multilayer film mirror is one quarter of a target emission wavelength.

According to the respective configurations, when the optical length of the micro-optical resonator is controlled and a target emission wavelength is optimized, a micro-optical resonator type organic electroluminescence device having high monochromaticity and high directionality in a forward direction can be obtained.

<Specific Configuration of Mirror>

A multilayer film mirror is a multilayer film in which two kinds of oxides, nitrides or semiconductors, which are different in refractive index from each other, are alternately layered. Typical examples of combinations thereof include multilayer films of dielectrics such as TiO₂ and SiO₂, SiNx and SiO₂, and Ta₂O₅ and SiO₂, and of semiconductors such as GaAs and GaInAs.

In the multilayer film mirror, light is reflected at interfaces of the respective layers. In order that lights reflected from the respective interfaces may strengthen each other, the thicknesses are set at λ/4 with respect to a wavelength (target emission wavelength) λ of light used.

(2) Resonator Structure with Two Opposite Electrodes as Mirrors

An organic electroluminescence device having a resonator structure with two opposite electrodes as mirrors has a resonator structure in which a first electrode and a second electrode are also functional as a first mirror and a second mirror and light generated in a light-emitting layer is resonated between the first electrode and the second electrode. An optical distance L₁ between the first electrode and the maximum emission position of the light-emitting layer satisfies Equation 9, and an optical length L₂ between the second electrode and the maximum emission position of the light-emitting layer satisfies Equation 10.
L₁=tL₁+a₁
(2tL₁)/λ=−φ₁/(2π)+m₁ (Equation 9)

In the equation, tL₁ expresses a theoretical optical distance between the first electrode and the maximum emission position, al expresses a correction factor based on an emission distribution in the light-emitting layer, λ expresses a peak wavelength in a spectrum of the target light, φ₁ expresses a phase shift of reflected light generated at the first electrode, and m₁ expresses an integer of 0 or an integer.
L₂=tL₂+a₂
(2tL₂)/λ=−φ₂/(2π)+m2 (Equation 10)

In the equation, tL₂ expresses a theoretical optical distance between the second electrode and the maximum emission position, a₂ expresses a correction factor based on an emission distribution in the light-emitting layer, λ expresses a peak wavelength in a spectrum of the target light, φ₂ expresses a phase shift of reflected light generated at the second electrode, and m₂ expresses an integer of 0 or an integer.

When light generated in the light-emitting layer is reflected at the first electrode or the second electrode to return to an emission position, a phase of the returned light and the phase at the time of emission become the same. Accordingly, the generated light and light reflected between the first electrode and the second electrode reinforce each other, whereby light generated at the light-emitting layer can be efficiently extracted.

12) Sealing

The organic electroluminescence device of the present invention may be sealed with a sealing cap over the whole device.

Furthermore, a moisture absorbent or an inert liquid may be used to seal a space defined between the sealing cap and the luminescent device. Although the moisture absorbent is not particularly restricted, specific examples thereof include barium oxide, sodium oxide, potassium oxide, calcium oxide, sodium sulfate, calcium sulfate, magnesium sulfate, phosphorus pentoxide, calcium chloride, magnesium chloride, copper chloride, cesium fluoride, niobium fluoride, calcium bromide, vanadium bromide, a molecular sieve, zeolite, magnesium oxide and the like. Although the inert liquid is not particularly limited, specific examples thereof include paraffins; liquid paraffins; fluorine-based solvents such as perfluoroalkanes, perfluoroamines, perfluoroethers and the like; chlorine-based solvents; silicone oils; and the like.

2. Producing Method of Element

The respective layers that constitute an element in the present invention can be preferably formed by any method of dry layering methods such as a vapor deposition method and a sputtering method, and wet layering methods such as a dipping method, a spin coating method, a dip coating method, a casting method, a die coating method, a roll coating method, a bar coating method and a gravure coating method.

Among these, from the viewpoints of emission efficiency and durability, the dry methods are preferable. In the case of the wet coating methods, a residual coating solvent unfavorably damages the light-emitting layer.

Particularly preferably, a resistance heating vacuum deposition method can be used. In the resistance heating vacuum deposition method, since only a substance that can be transpired by heating under a vacuum atmosphere can be efficiently heated, whereby the element is not exposed to a high temperature, the element is advantageously subjectedd to less damage.

The vacuum deposition method is a method in which, in a vacuumed vessel, a deposition material is heated to vaporize or sublimate to deposit on a surface of an adherend disposed at a slightly distanced position to form a thin film. Depending on the kind of the deposition material and the adherend, resistance heating, an electron beam, high-frequency induction, laser or the like is used to carry out heating. Among these, the one that can form a layer with at the lowest temperature is the resistance heating vacuum deposition method. Although it cannot form a layer with a material having a high sublimation temperature, all materials that have a low sublimation temperature can form a layer in a state where the adherent material is hardly thermally affected.

The sealing film material in the present invention can form a layer by means of the resistance heating vacuum deposition method.

A conventional sealing material such as silicon oxide, being high in sublimation temperature, has been impossible to deposit by means of resistance heating. Furthermore, in a vacuum deposition method such as an ion plating method generally described in known examples, since a vaporizing portion becomes such a high temperature as several thousands of degrees centigrade to adversely thermally affect and modify an adherent material, this method is not appropriate as a producing method of a sealing film of an organic EL device that is particularly easily affected by heat and UV rays.

3. Driving Method

In the organic electroluminescence device of the present invention, when a DC (AC components may be contained as occasion arises) voltage (usually 2 volts to 15 volts) or DC is applied across the anode and the cathode, luminescence can be obtained.

The driving durability of the organic electroluminescence device in the present invention can be determined based on the brightness halftime at a specified brightness. For instance, the brightness halftime may be determined in such a manner that a source measuring unit, model 2400, manufactured by KEITHLEY is used to apply a DC voltage to the organic EL device to thereby emit light, a continuous driving test is conducted under the condition of an initial brightness of 2000 cd/m², when the brightness reaches 1000 cd/m², the period of time required therefore is desired as the brightness halftime T (½), and then, the resulting brightness halftime is compared with that of a conventional luminescent device. In the present invention, the numerical value thus obtained is used.

An important characteristic parameter of the organic electroluminescence device of the present invention is external quantum efficiency. The external quantum efficiency is calculated by “the external quantum efficiency (φ)=the number of photons emitted from the device/the number of electrons injected to the device”, and it may be said that the larger the value obtained, the more advantageous the device is in the view of electric power consumption.

Moreover, the external quantum efficiency of the organic electroluminescence device is determined by “the external quantum efficiency (φ)=the internal quantum efficiency×light-extraction efficiency”. In an organic EL device which utilizes fluorescent luminescence from an organic compound, an upper limit of the internal quantum efficiency is 25% while the light-extraction efficiency is about 20%, and accordingly it is considered that an upper limit of the external quantum efficiency is about 5%. In an organic EL device which utilizes phosphorescent luminescence from an organic compound, an upper limit of the internal quantum efficiency is 100% while the light-extraction efficiency is about 20%, and accordingly it is considered that an upper limit of the external quantum efficiency is about 20%. Therefore, the phosphorescent luminescence is more favorable than the fluorescent luminescence.

From the viewpoint of being capable of reducing the power consumption as well as the viewpoint of being capable of increasing the driving durability, the external quantum efficiency of a device is preferably 6% or more, and particularly preferably is 12% or more.

The numerical value of the external quantum efficiency may take the maximum value thereof when in the case of driving the device at 20° C., or a value of the external quantum efficiency at about 100 cd/m² to 300 cd/m² (preferably 200 cd/m²) when in the case of driving the device at 20° C.

In the present invention, the value obtained by the following method is used. Namely, the method is such that a DC constant voltage is applied to the EL device by the use of a source measuring unit, model 2400, manufactured by Toyo TECHNICA Corporation to emit a light, the brightness of the light is measured by using a brightness photometer (trade name: BM-8, manufactured by Topcon Corporation), and then, the external quantum efficiency at 200 cd/m² is calculated.

On the other hand, an external quantum efficiency of the luminescent device may be obtained in such a manner that the luminescent brightness, the luminescent spectrum, and the current density are measured, and the external quantum efficiency is calculated from these results and a specific visibility curve. In other words, using the current density value, the number of electrons injected can be calculated. By an integration calculation using the luminescent spectrum and the specific visibility curve (spectrum), the luminescent brightness can be converted into the number of photons emitted. From the result, the external quantum efficiency (%) can be calculated by “(the number of photons emitted/the number of electrons injected to the device)×100”.

For the driving method of the organic electroluminescence device of the present invention, the driving methods described in JP-A Nos. 2-148687, 6-301355, 5-29080, 7-134558, 8-234685, and 8-241047; Japanese Patent No. 2784615, U.S. Pat. Nos. 5,828,429 and 6,023,308 are applicable.

(Application of the Organic Electroluminescence Device of the Present Invention)

The organic electroluminescence device of the present invention can be appropriately used for indicating elements, displays, backlights, electronic photographs, illumination light sources, recording light sources, exposure light sources, reading light sources, marks, advertising displays, interior accessories, optical communications and the like.

### EXAMPLES

In the following, the present invention will be more specifically described with reference to examples. However, the present invention is not restricted by the examples described below.

First, three light-emitting laminates used in examples of the present invention will be described.

(Preparation of Light-emitting Laminate A)

The light-emitting laminate A is a bottom emission type organic electroluminescence device.

As a substrate, a 2.5 cm square glass plate having a thickness of 0.7 mm with an ITO film attached thereto (thickness of ITO film: 150 nm) was used. A width of an ITO electrode was set at 2 mm.

The following functional layers were sequentially deposited thereon all by means of the resistance heating vacuum deposition method.

Functional layers: 2-TNATA layer with a thickness of 170 nm/NPD layer with a thickness of 10 nm/Alq3 layer with a thickness of 50 nm/LiF layer with a thickness of 0.5 nm

Thereon, Al with a thickness of 100 nm was deposited as a second electrode (cathode) by means of the resistance heating vacuum deposition method. A width of the Al electrode was set at 2 mm.

(Preparation of Light-emitting Laminate B)

The light-emitting laminate B is a top emission mode organic electroluminescence device.

Using a 2.5 cm square glass plate with a thickness of 0.7 mm as a substrate, an Al film with a thickness of 100 nm was deposited as a reflective layer by means of the resistance heating vacuum deposition method, followed by spin coating a resin layer (acrylic resin) with a thickness of 2000 nm.

Furthermore, an ITO film with a thickness of 150 nm was formed as an anode by means of the argon sputtering method, followed by etching to shape the anode to a width of 2 mm.

Thereon, the following functional layers were sequentially deposited all by means of the resistance heating vacuum deposition method.

Functional layers: 2-TNATA layer with a thickness of 170 nm/NPD layer with a thickness of 10 nm/Alq3 layer with a thickness of 50 nm/LiF layer with a thickness of 0.5 nm

Thereon, Al with a thickness of 1.5 nm and an Ag layer with a thickness of 15 nm were deposited as a second electrode (cathode) by means of the resistance heating vacuum deposition method.

(Preparation of Light-emitting Laminate C)

The light-emitting laminate C is a multiple interference type top emission organic electroluminescence device.

Using a 2.5 cm square glass plate with a thickness of 0.7 mm as a substrate, an Al film with a thickness of 60 nm was deposited as a first electrode (anode) by means of the resistance heating vacuum deposition method.

Thereon, following functional layers were sequentially deposited all by means of the resistance heating vacuum deposition method.

Functional layers: MoO₃ layer with a thickness of 2 nm/layer containing 10% by mass of MoO₃ to 2-TNATA by means of a co-deposition method (20 nm)/2-TNATA layer with a thickness of 170 nm/NPD layer with a thickness of 10 nm/Alq3 layer with a thickness of 50 nm/LiF layer with a thickness of 0.5 nm

Thereon, Al with a thickness of 1.5 nm and an Ag layer with a thickness of 15 nm were deposited as a second electrode (cathode) by means of the resistance heating vacuum deposition method.

### Examples 1 through 4

On the second electrode (cathode) of the light-emitting laminate A, a first protective layer and a second protective layer, which are shown in Table 1, were sequentially disposed all by means of the resistance heating vacuum deposition method.

### Examples 5 through 8

On the second electrode (cathode) of the light-emitting laminate B, a first protective layer and a second protective layer, which are shown in Table 1, were sequentially disposed all by means of the resistance heating vacuum deposition method.

### Examples 9 through 12

On the second electrode (cathode) of the light-emitting laminate C, a first protective layer and a second protective layer, which are shown in Table 1, were sequentially disposed all by means of the resistance heating vacuum deposition method.

### Comparative Examples 1 through 3

On the second electrode (cathode) of the light-emitting laminate C, a first protective layer and a second protective layer, which are shown in Table 1, were sequentially disposed.

An LiF layer with a thickness of 100 nm of comparative example 1 was disposed according to an ion plating method described in JP-A No. 6-96858.

An LiF layer with a thickness of 100 nm of comparative example 2 was disposed according to the ion plating method described in JP-A No. 6-96858, followed by disposing a thermosetting epoxy resin layer with a thickness of 2000 nm according to a solvent coating method described in JP-A No. 2001-338755.

In comparative example 3, according to a method described in JP-A No. 2005-235585, as a first protective layer, a PEDOT (polyethylene-dioxythiophene) layer containing 10% by mass of CaO as a desiccating agent was disposed by means of the resistance heating vacuum deposition method, and, as a second protective layer, an SiO₂ layer with a thickness of 80 nm was disposed according to the argon sputtering method.

(Performance Evaluation)

The prepared organic electroluminescence devices were evaluated according to methods described below.

<Emission Efficiency and Dark Spot>

To each of the elements, immediately after preparation, a direct current voltage was applied with a SOURCE MEASURE UNIT 2400 (trade name, produced by Toyo Technica Corp.), to cause light emission and an initial emission performance was measured. The emission efficiency at 2000 Cd/m² was measured.

The emission efficiency was expressed as a relative emission efficiency with the emission efficiency of example 1 designated as 1.0. 0

Dark spots were observed with an optical microscope ME600 (trade name, produced by Nikon Corp.).

Herein, in an electroluminescence device region that is interposed between a cathode and an anode and is supposed to emit originally, a region that does not emit light is defined as a dark spot. By image processing a photograph of the emission surface, an area ratio of a non-emitting region was obtained. Providing that a case where the entire 2 mm×2 mm region emits light is designated as 1.0, initial dark spot rates of the respective elements are shown in Table 2.

<Driving Durability Test>

With a SOURCE MEASURE UNIT 2400 (trade name, produced by Keithley Instrument Inc.,), a direct current voltage was applied to a light-emitting device to cause light emission. The brightness thereof was measured with a Brightness Meter BM-8 (trade name, produced by Topcon Corp.).

Subsequently, the light-emitting element was subjected to a continuous driving test under a constant driving current and a time until the brightness became one half was defined as a brightness half-life period T (½). Current values were controlled so that the initial brightness of all of the elements were the same.

The brightness half-life period was expressed by a relative value with the brightness half-life period of example 1 designated as 1.0.

<Light Transmittance of First Protective Layer>

Each of PEDOT used in preparation of a sealing element A3 for comparison and a first protective layer material used in the sealing element of the present invention was deposited on a glass substrate at a thickness the same as that in each of the sealing elements to prepare samples for measurement. The visible light transmittance of the obtained samples was measured with a spectrophotometer. The visible transmittance was expressed with the light transmittance at 550 nm as a representative value.

TABLE 1

| | Light- | First Protective Layer | | Second Protective Layer | |
|---|---|---|---|---|---|
| | Emitting | | Thickness | | Thickness |
| Test No. | Laminate | Material | (nm) | Material | (nm) |
| Example 1 | A | 2-TNTA | 50 | LiF | 50 |
| Example 2 | A | MeCBP | 30 | 2-TNTA | 20 |
| | | MgF | 30 | LiF | 20 |
| Example 3 | A | MeCBP | 50 | MgF/LiF = 50/50 | 50 |
| | | | | (mass ratio) | |
| Example 4 | A | MeCBP/2-TNTA = 50/50 | 50 | LiF | 50 |
| | | (mass ratio) | | | |
| Example 5 | B | 2-TNTA | 50 | LiF | 50 |
| Example 6 | B | MeCBP | 30 | 2-TNTA | 20 |
| | | MgF | 30 | LiF | 20 |
| Example 7 | B | MeCBP | 50 | MgF/LiF = 50/50 | 50 |
| | | | | (mass ratio) | |
| Example 8 | B | MeCBP/2-TNTA = 50/50 | 50 | LiF | 50 |
| | | (mass ratio) | | | |
| Example 9 | C | 2-TNTA | 50 | LiF | 50 |
| Example 10 | C | MeCBP | 30 | 2-TNTA | 20 |
| | | MgF | 30 | LiF | 20 |
| Example 11 | C | MeCBP | 50 | MgF/LiF = 50/50 | 50 |
| | | | | (mass ratio) | |
| Example 12 | C | MeCBP/2-TNTA = 50/50 | 50 | LiF | 50 |
| | | (mass ratio) | | | |
| Comparative 1 | C | LiF | 100 | — | — |
| Comparative 2 | C | LiF | 100 | Thermosetting | 2000 |
| | | | | Epoxy Resin | |
| | | | | (2000 nm) | |
| Comparative 3 | C | PEDOT/CaO = 90/10 | 100 | SiO2 | 80 |
| | | (mass ratio) | | | |

Obtained results are shown in Table 2. From the results, the electroluminescence devices according to the present invention were improved with respect to dark spot incidence, high in emission efficiency, and excellent in driving durability. Furthermore, the visible light transmittance was 90% or more for all of the devices of the present invention, and the electroluminescence devices could be sufficiently applied to the top emission mode.

On the other hand, in devices according to comparative examples 1 through 3, many dark spots were observed. Furthermore, in the devices according to comparative examples 1 through 3, the emission efficiencies were deteriorated and the driving durability was deteriorated as well.

TABLE 2

| | Light | | | |
|---|---|---|---|---|
| | Transmittance | | | |
| | of Protective | Dark Spot | Emission | Half-life |
| Test No. | Layer (%) | Rate (%) | Efficiency | Period (hr) |
| Example 1 | 93 | 1.0 | 1.0 | 1.0 |
| Example 2 | 90 | 1.0 | 1.0 | 1.1 |
| Example 3 | 92 | 1.0 | 1.0 | 1.0 |
| Example 4 | 92 | 1.0 | 1.0 | 1.0 |
| Example 5 | 93 | 1.0 | 0.7 | 0.7 |
| Example 6 | 90 | 1.0 | 0.7 | 0.8 |
| Example 7 | 92 | 1.0 | 0.7 | 0.7 |
| Example 8 | 92 | 1.0 | 0.7 | 0.7 |
| Example 9 | 93 | 1.0 | 0.8 | 0.8 |
| Example 10 | 90 | 1.0 | 0.8 | 0.9 |
| Example 11 | 92 | 1.0 | 0.8 | 0.8 |
| Example 12 | 92 | 1.0 | 0.8 | 0.8 |
| Comparative 1 | 89 | 0.7 | 0.5 | 0.4 |
| Comparative 2 | 88 | 0.4 | 0.6 | 0.5 |
| Comparative 3 | 42 | 0.9 | 0.4 | 0.2 |

What is claimed is:

1. An organic electroluminescence device comprising on a substrate, in the following order, a first electrode, at least one organic compound layer including a light-emitting layer, a second electrode, and a protective layer, wherein the protective layer includes two or more layers, a first protective layer closer to the second electrode is an electrically insulating layer containing an organic compound, and a second protective layer farther from the second electrode is a layer containing a metal halide.

2. The organic electroluminescence device according to claim 1, wherein the layer containing a metal halide contains at least one metal halide selected from lithium fluoride, calcium fluoride, potassium fluoride, sodium fluoride, cesium fluoride, magnesium fluoride, potassium chloride, sodium chloride, lithium chloride and potassium bromide.

3. The organic electroluminescence device according to claim 1, wherein the organic compound contained in the electrically insulating layer has an average molecular weight of 1500 or less.

4. The organic electroluminescence device according to claim 3, wherein the electrically insulating layer has a light-transmittance of 60% or more over the entire visible region.

5. The organic electroluminescence device according to claim 2, wherein a thickness of the layer containing the metal halide is 10 nm to 1000 nm.

6. The organic electroluminescence device according to claim 3, wherein a thickness of the electrically insulating layer is 10 nm to 1000 nm.

7. The organic electroluminescence device according to claim 1, wherein the organic electroluminescence device is a top emission mode device in which light emitted from the light-emitting layer is radiated in a direction opposite from the substrate.

8. The organic electroluminescence device according to claim 1, wherein the organic electroluminescence device has a resonant structure in which light generated in the light-emitting layer is resonated between the electrodes, and in which one of the first electrode or the second electrode is a reflective electrode and the other is a translucent electrode.

9. The organic electroluminescence device according to claim 8, wherein the first electrode is the reflective electrode, and the second electrode is the translucent electrode.

10. A producing method of an organic electroluminescence device that includes, on a substrate, in the following order, a first electrode, at least an organic compound layer including a light-emitting layer, a second electrode and a protective layer, wherein the protective layer includes two or more layers, a first protective layer closer to the second electrode being an electrically insulating layer containing an organic compound, and a second protective layer farther from the second electrode being a metal halide layer, wherein the producing method comprises a process of sequentially forming the electrodes and the respective layers by means of a resistance heating vacuum deposition method.

11. The producing method of an organic electroluminescence device according to claim 10, wherein the metal halide layer is formed from at least one metal halide selected from lithium fluoride, calcium fluoride, potassium fluoride, sodium fluoride, cesium fluoride, magnesium fluoride, potassium chloride, sodium chloride, lithium chloride and potassium bromide by means of a resistance heating vacuum deposition method.

12. The producing method of an organic electroluminescence device according to claim 10, wherein the electrically insulating layer is formed from an organic compound having an average molecular weight of 1500 or less by means of a resistance heating vacuum deposition method.

13. The producing method of an organic electroluminescence device according to claim 12, wherein the electrically insulating layer has a light-transmittance of 60% or more over the entire visible region.

14. The producing method of an organic electroluminescence device according to claim 11, wherein a thickness of the metal halide layer is 10 nm to 1000 nm.

15. The producing method of an organic electroluminescence device according to claim 12, wherein a thickness of the electrically insulating layer is 10 nm to 1000 nm.
